(19) United States
(12) Patent Application Publication
(10) Pub. No.: US 2023/0209848 A1
(43) Pub. Date: Jun. 29, 2023

(54) QUANTUM DOT DEVICE AND ELECTRONIC DEVICE

(71) Applicant: SAMSUNG ELECTRONICS CO., LTD., Suwon-si (KR)

(72) Inventors: Hong Kyu SEO, Suwon-si (KR); Kwanghee KIM, Suwon-si (KR); Kunsu PARK, Suwon-si (KR); Eun Joo JANG, Suwon-si (KR); Hyo Sook JANG, Suwon-si (KR); You Jung CHUNG, Suwon-si (KR); Soonmin CHA, Suwon-si (KR)

(21) Appl. No.: 18/057,242

(22) Filed: Nov. 21, 2022

(30) Foreign Application Priority Data
Dec. 27, 2021 (KR) 10-2021-0188512

(51) Int. Cl. H10K 50/11; H10K 50/16; H10K 50/17

(52) U.S. Cl. CPC H01L 51/5004; H01L 51/508; H01L 51/5092; H01L 2251/303

(57) ABSTRACT

A quantum dot device and an electronic device. The quantum dot device includes a first electrode and an opposite facing second electrode, a light emitting layer disposed between the first electrode and the second electrode and including quantum dots, a first electron auxiliary layer proximate to the light emitting layer and disposed between the second electrode and the light emitting layer and including a first electron auxiliary material, a second electron auxiliary layer proximate to the second electrode and disposed between the second electrode and the light emitting layer and including a second electron auxiliary material, and an insertion layer disposed between the first electron auxiliary layer and the second electron auxiliary layer and including an inorganic material, wherein a HOMO energy level of the inorganic material is deeper than a HOMO energy level of the first electron auxiliary material, and a HOMO energy level of the second electron auxiliary material, respectively.

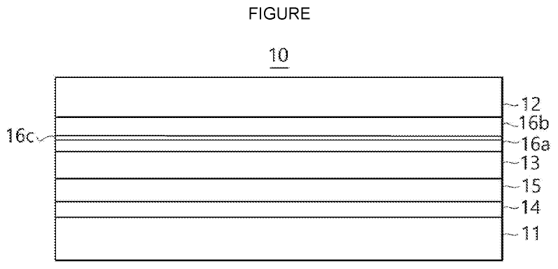

### CROSS-REFERENCE TO RELATED APPLICATION

This application claims priority to Korean Patent Application No. 10-2021-0188512 filed in the Korean Intellectual Property Office on Dec. 27, 2021, and all the benefits accruing therefrom under 35 U.S.C. § 119, the content of which in its entirety is herein incorporated by reference.

### BACKGROUND OF THE INVENTION

### Field of the Invention

A quantum dot device and an electronic device including the quantum dot device are disclosed.

### Description of the Related Art

Nanostructures such as quantum dots (hereinafter, referred to as quantum dots) are semiconductor materials in the form of particles having a nanoscale size and may exhibit a quantum confinement effect and may exhibit luminescence. Light emission of quantum dots may be generated when electrons in an excited state transit from a conduction band to a valence band, for example, by light excitation or by application of a voltage. Quantum dots may be structured to emit light of a desired wavelength region by controlling their sizes and/or compositions.

### SUMMARY OF THE INVENTION

An embodiment provides a quantum dot device capable of realizing improved performance.

An embodiment provides an electronic device including the quantum dot device.

According to an embodiment, a quantum dot device includes a first electrode and an opposite facing second electrode, a light emitting layer disposed between the first electrode and the second electrode, the light emitting layer including quantum dots, a first electron auxiliary layer proximate to the light emitting layer and disposed between the second electrode and the light emitting layer, and including a first electron auxiliary material, a second electron auxiliary layer proximate to the second electrode and disposed between the second electrode and the light emitting layer, and including a second electron auxiliary material, and an insertion layer disposed between the first electron auxiliary layer and the second electron auxiliary layer and including an inorganic material, wherein a HOMO energy level of the inorganic material is deeper than a HOMO energy level of the first electron auxiliary material, and a HOMO energy level of the second electron auxiliary material, respectively.

An energy bandgap of the inorganic material may be greater than an energy bandgap of the first electron auxiliary material, and an energy bandgap of the second electron auxiliary material, respectively.

The inorganic material may be inorganic nanoparticles having an energy bandgap of greater than or equal to about 4.5 electron Volts (eV).

The inorganic nanoparticles may be metal oxide nanoparticles or semi-oxide nanoparticles including Si, Al, Zr, Mg, Ca, Hf, Y, La, or a combination thereof.

The inorganic material may be silica.

The first electron auxiliary material and the second electron auxiliary material may include n-type inorganic nanoparticles.

The first electron auxiliary material and the second electron auxiliary material may independently include n-type inorganic nanoparticles represented by Zn₁₋ₓQₓO, wherein Q is at least one metal other than Zn and 0≤x<0.5, respectively.

The first electron auxiliary material and the second electron auxiliary material may be the same.

A thickness of the insertion layer may be greater than or equal to about 1 nanometer (nm) and less than about 10 nm.

A thickness of the first electron auxiliary layer may be the same as or greater than a thickness of the insertion layer, and a thickness of the second electron auxiliary layer may be greater than a thickness of the first electron auxiliary layer.

The thickness of the second electron auxiliary layer may be about 2 times to about 10 times greater than the first electron auxiliary layer.

Each of the first electron auxiliary layer and the insertion layer may have a thickness of greater than or equal to about 1 nm and less than about 10 nm, and the thickness of the second electron auxiliary layer may be greater than the first electron auxiliary layer.

According to some example embodiments, a quantum dot device includes a first electrode and an opposite facing second electrode, a light emitting layer disposed between the first electrode and the second electrode and including quantum dots, a first electron auxiliary layer proximate to the light emitting layer and disposed between the second electrode and the light emitting layer, and including first inorganic nanoparticles, a second electron auxiliary layer proximate to the second electrode and disposed between the second electrode and the light emitting layer, and including the first inorganic nanoparticles, and an insertion layer disposed between the first electron auxiliary layer and the second electron auxiliary layer and including second inorganic nanoparticles having an energy bandgap greater than that of the first inorganic nanoparticles.

An energy bandgap of the first inorganic nanoparticles may be greater than or equal to about 2.0 eV and less than about 4.0 eV, and an energy bandgap of the second inorganic nanoparticles of the insertion layer may be about 4.5 eV to 10.0 eV.

A HOMO energy level of the second inorganic nanoparticles of the insertion layer may be deeper than a HOMO energy level of the first inorganic nanoparticles.

A difference between the HOMO energy level of the second inorganic nanoparticles of the insertion layer and the HOMO energy level of the first inorganic nanoparticles may be about 0.1 eV to about 5.0 eV.

The first inorganic nanoparticles may be oxide nanoparticles represented by Zn₁₋ₓQₓO, wherein Q is at least one metal other than Zn and 0≤x<0.5, and the second inorganic nanoparticles may be oxide nanoparticles including Si, Al, Zr, Mg, Ca, Hf, Y, La, or a combination thereof.

A thickness of the insertion layer may be about 1 nm to about 8 nm.

A thickness of the first electron auxiliary layer may be greater than or equal to about 1 nm and less than about 10 nm, and the thickness of the second electron auxiliary layer may be greater than the insertion layer.

According to some example embodiments, an electronic device including the quantum dot device is provided.

The performance of quantum dot devices may be improved.

### BRIEF DESCRIPTION OF THE DRAWING

The FIGURE is a schematic cross-sectional view illustrating a quantum dot device according to some example embodiments.

### DETAILED DESCRIPTION OF THE EMBODIMENTS

Hereinafter, embodiments of the present disclosure will be described in detail so that a person skilled in the art would understand the same. This disclosure may, however, be embodied in many different forms and is not construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The terms “first,” “second,” “third,” etc., may be used herein to describe various elements, components, regions, layers, and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% or ±3% of the stated value. Ranges are inclusive of the endpoint of the value(s) stated.

Exemplary embodiments are described herein with reference to a cross section illustration that is a schematic illustration an embodiment. As such, variations from the shapes of the illustration as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the average (value) may be mean or median. In an embodiment, the average (value) may be a mean average.

As used herein, when a definition is not otherwise provided, “substituted” refers to replacement of a, e.g., at least one, hydrogen of a compound or the corresponding moiety by a C1 to C30 alkyl group, a C1 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM′, wherein M′ is an organic or inorganic cation), a sulfonic acid group (—SO₃H) or a salt thereof (—SO₃M′, wherein M′ is an organic or inorganic cation), a phosphoric acid group (—PO₃H₂) or a salt thereof (—PO₃M′H or —PO₃M′₂, wherein M′ is an organic or inorganic cation), or a combination thereof. The total number of carbon atoms in a group is inclusive of any substituents, e.g., a cyanoethyl group is a substituted C3 alkyl group.

The term “combination” includes a mixture and a laminated structure of two or more.

As used herein, when specific definition is not otherwise provided, an energy level refers to the highest occupied molecular orbital (HOMO) energy level, or the lowest unoccupied molecular orbital (LUMO) energy level, in the context as understood by a person of ordinary skill.

The HOMO energy level and work function may be measured by ultraviolet photoelectron spectroscopy (UPS), and the LUMO energy level may be calculated from the energy bandgap obtained at the absorption peak and the HOMO energy level. A work function, a HOMO energy level, or a LUMO energy level is expressed as an absolute value from a vacuum level. In addition, when the work function, HOMO energy level, or LUMO energy level is referred to be deep, high, or large, it may have a large absolute value based on “0 eV” of the vacuum level while when the work function, HOMO energy level, or LUMO energy level is referred to be shallow, low, or small, it may have a small absolute value based on “0 eV” of the vacuum level.

The term “metal” includes a metal and a semi-metal.

As used herein, the expression that “not including cadmium (or other harmful heavy metal)” refers to the case where a concentration of the cadmium (or the harmful heavy metal) may be less than or equal to about 100 ppm, less than or equal to about 50 ppm, less than or equal to about 10 ppm, or almost zero. In an embodiment, substantially no amount of the cadmium (or other heavy metal) may be present or, if present, an amount of the cadmium (or other heavy metal) may be less than or equal to a detection limit or as an impurity level of a given analysis tool.

As used herein, “Group” in terms of Group II, Group III, etc. refers to a group of the periodic table of elements.

As used herein, “Group II” may refer to Group IIA and Group IIB, and examples of Group II metal may be Cd, Zn, Hg, and Mg, but are not limited thereto.

As used herein, “Group III” may refer to Group IIIA and Group IIIB, and examples of Group III metal may be Al, In, Ga, and TI, but are not limited thereto.

As used herein, “Group IV” may refer to Group IVA and Group IVB, and examples of a Group IV metal may be Si, Ge, and Sn, but are not limited thereto. As used herein, the term “metal” may include a semi-metal such as Si.

As used herein, “Group I” may refer to Group IA and Group IB and examples of the Group I element may be Li, Na, K, Rb, or Cs but are not limited thereto.

As used herein, “Group V” may refer to Group VA, and examples may include nitrogen, phosphorus, arsenic, antimony, and bismuth, but are not limited thereto.

As used herein, “Group VI” may refer to Group VIA, and examples may include sulfur, selenium, and tellurium, but are not limited thereto.

Hereinafter, a quantum dot device according to some example embodiments is described with reference to the drawings.

The quantum dot device according to some example embodiments may be a quantum dot electroluminescent device configured to emit light from the quantum dot by applying a voltage across the electrodes.

The FIGURE is a schematic cross-sectional view illustrating a quantum dot device according to some example embodiments.

Referring to the FIGURE, a quantum dot device 10 includes a first electrode 11 and a second electrode 12 facing each other; a light emitting layer 13 disposed between the first electrode 11 and the second electrode 12; a first hole auxiliary layer 14 and a second hole auxiliary layer 15 disposed between the first electrode 11 and the light emitting layer 13; and a first electron auxiliary layer 16a, a second electron auxiliary layer 16b, and an insertion layer 16c disposed between the second electrode 12 and the light emitting layer 13.

The substrate (not shown) may be disposed at an opposite side of the first electrode 11 or may be disposed at an opposite side of the second electrode 12. The substrate may be, for example, made of an inorganic material such as glass; an organic material such as polycarbonate, polymethylmethacrylate, polymethylacrylate, polyethylene terephthalate, polyethylene naphthalate, polyamide, polyethersulfone, or a combination thereof; or a silicon wafer. The substrate may be omitted.

One of the first electrode 11 and the second electrode 12 is an anode and the other is a cathode. For example, the first electrode 11 may be an anode and the second electrode 12 may be a cathode. For example, the first electrode 11 may be a cathode and the second electrode 12 may be an anode.

The first electrode 11 may be made of a conductor having a relatively high work function, for example, a metal, a conductive metal oxide, or a combination thereof. The first electrode 11 may be made of, for example, a metal or an alloy thereof such as nickel, platinum, vanadium, chromium, copper, zinc, or gold; a conductive metal oxide such as zinc oxide, indium oxide, tin oxide, indium tin oxide (ITO), indium zinc oxide (IZO), or a fluorine-doped tin oxide; or a combination of metal and oxide such as ZnO and Al or SnO₂ and Sb, but is not limited thereto.

The second electrode 12 may be made of a conductor having a lower work function than the first electrode 11, and may be made of, for example, a metal, a conductive metal oxide, and/or a conductive polymer. The second electrode 12 may include, for example, a metal such as aluminum, magnesium, calcium, sodium, potassium, titanium, indium, yttrium, lithium, gadolinium, silver, tin, lead, cesium, barium, or an alloy thereof; and a multilayer structure material such as LiF/Al, Li₂O/Al, Liq/Al, LiF/Ca, and BaF₂/Ca, but is not limited thereto.

A work function of the first electrode 11 may be higher than a work function of the second electrode 12, for example the work function of the first electrode 11 may be, for example, about 4.5 eV to about 5.0 eV and the work function of the second electrode 12 may be about 4.0 eV to about 4.7 eV. Within the above range, the work function of the first electrode 11 may be, for example, about 4.6 eV to about 4.9 eV, and the work function of the second electrode 12 may be, for example, about 4.0 eV to about 4.5 eV.

At least one of the first electrode 11 or the second electrode 12 may be a light-transmitting electrode and the light-transmitting electrode may be for example made of a conductive oxide such as a zinc oxide, indium oxide, tin oxide, indium tin oxide (ITO), indium zinc oxide (IZO), or fluorine-doped tin oxide, or a metal thin layer which may be a single layer or a multilayer. Any one of the first electrode 11 or the second electrode 12 may be an opaque electrode, and the opaque electrode may be made of, for example, an opaque conductor such as aluminum (Al), silver (Ag), or gold (Au).

The light emitting layer 13 includes a quantum dot (quantum dots, hereinafter referred to as quantum dot) as a light emitter configured to emit light upon application of an electric field. The quantum dot means a semiconductor nanocrystal in a broad sense and may exhibit a quantum confinement effect. Here, the quantum dot may have any shape, and are not particularly limited. In one non-limiting example, the quantum dot may have various shapes, such as an isotropic semiconductor nanocrystal, a quantum rod, and/or a quantum plate. Here, the quantum rod may mean a quantum dot having an aspect ratio of length to width of greater than about 1:1, for example, an aspect ratio of greater than or equal to about 2:1, greater than or equal to about 3:1, or greater than or equal to about 5:1. For example, an aspect ratio of length to width of the quantum rod may be less than or equal to about 50:1, less than or equal to about 30:, or less than or equal to about 20:1.

The quantum dot may have, for example a particle diameter (a largest particle diameter for a non-spherical shape) of about 1 nm to about 100 nm, for example, about 1 nm to about 80 nm, for example, about 1 nm to about 50 nm, for example, about 1 nm to about 20 nm. In an example, the (average) size of the quantum dot(s) may be greater than or equal to about 1 nm, greater than or equal to about 2 nm, greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, or greater than or equal to about 12 nm. In an example, the (average) size of the quantum dot(s) may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, or less than or equal to about 15 nm. For example, the average size of quantum dot (e.g., emitting blue light) may be, for example, less than or equal to about 4.5 nm, for example, less than or equal to about 4.3 nm, less than or equal to about 4.2 nm, less than or equal to about 4.1 nm, or less than or equal to about 4.0 nm. In an example, the (average) size of the quantum dot may be about 2.0 nm to about 4.5 nm, about 2.0 nm to about 4.3 nm, about 2.0 nm to about 4.2 nm, about 2.0 nm to about 4.1 nm, or about 2.0 nm to about 4.0 nm.

An energy bandgap of the quantum dot may be adjusted according to size and/or composition, and the emission wavelength may be adjusted accordingly. For example, as the size of the quantum dot increases, the energy bandgap may decrease, and thus, light in a relatively long wavelength region may be emitted. As the size of the quantum dot decreases, the energy bandgap may increase, and thus light in a relatively short wavelength region may be emitted.

For example, the quantum dot may be configured to emit light in, for example, a predetermined wavelength region within the visible region according to their respective size and/or composition. For example, a quantum dot may be configured to emit blue light, red light or green light. The blue light may have a peak emission wavelength, for example at about 430 nm to about 480 nm, red light may have a peak emission wavelength at about 600 nm to about 670 nm, and green light may have a peak emission wavelength at about 500 nm to about 560 nm.

In the quantum dot device 10 of an example embodiment, a maximum emission wavelength of the light emitting layer 13 may be greater than or equal to about 300 nm, greater than or equal to about 400 nm, greater than or equal to about 430 nm, greater than or equal to about 450 nm, for example, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The maximum emission wavelength of the quantum dot may be in the range of less than or equal to about 800 nm, less than or equal to about 780 nm, less than or equal to about 750 nm, for example, less than or equal to about 700 nm, less than or equal to about 670 nm, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The maximum emission wavelength of the quantum dots may be in the range of about 430 nm to about 670 nm.

In the quantum dot device 10 of an example embodiment, the light emitting layer 13 or quantum dot(s) may be configured to emit green light, and the maximum emission wavelength may be in the range of greater than or equal to about 500 nm (e.g., greater than or equal to about 510 nm or greater than or equal to about 520 nm) and less than or equal to about 560 nm (e.g., less than or equal to about 550 nm or less than or equal to about 540 nm).

In the quantum dot device 10 of an example embodiment, the light emitting layer 13 or quantum dot(s) may be configured to emit red light and the maximum emission wavelength may be in the range of greater than or equal to about 600 nm (e.g., may be greater than or equal to about 610 nm) and less than or equal to about 670 nm (e.g., less than or equal to about 650 nm or less than or equal to about 640 nm).

In the quantum dot device 10 of an example embodiment, the light emitting layer 13 or quantum dot(s) may be configured to emit blue light and the maximum emission wavelength may be in the range of greater than or equal to about 430 nm (e.g., greater than or equal to about 440 nm or greater than or equal to about 450 nm) and less than or equal to about 480 nm (e.g., less than or equal to about 470 nm or less than or equal to about 465 nm).

The quantum dot may have a quantum yield of greater than or equal to about 10%, for example, greater than or equal to about 20%, greater than or equal to about 30%, greater than or equal to about 50%, greater than or equal to about 60%, greater than or equal to about 70%, or greater than or equal to about 90%.

The emission spectrum of the quantum dot may have a relatively narrow full width at half maximum (FWHM). Herein, the FWHM is a width of a wavelength corresponding to half of the maximum emission point in the emission spectrum. By applying the quantum dot having an emission spectrum of a relatively narrow FWHM and the light emitting layer 13 including the same to the quantum dot device 10, high color purity (or color reproducibility) may be realized.

The FWHM of the quantum dot (or light emitting layer 13) may be for example less than or equal to about 60 nm, for example, less than or equal to about 55 nm, less than or equal to about 52 nm, less than or equal to about 50 nm, less than or equal to about 49 nm, less than or equal to about 48 nm, less than or equal to about 47 nm, less than or equal to about 46 nm, less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, less than or equal to about 35 nm, less than or equal to about 34 nm, less than or equal to about 33 nm, less than or equal to about 32 nm, less than or equal to about 31 nm, less than or equal to about 30 nm, less than or equal to about 29 nm, or less than or equal to about 28 nm.

The FWHM of the quantum dot (or light emitting layer 13) may be, for example, in a range from about 2 nm to about 60 nm, about 2 nm to about 55 nm, about 2 nm to about 50 nm, about 2 nm to about 49 nm, about 2 nm to about 48 nm, about 2 nm to about 47 nm, about 2 nm to about 46 nm, about 2 nm to a 45 nm, about 2 nm to about 44 nm, about 2 nm to about 43 nm, about 2 nm to about 42 nm, about 2 nm to about 41 nm, about 2 nm to about 40 nm, about 2 nm to about 39 nm, about 2 nm to about 38 nm, about 2 nm to about 37 nm, about 2 nm to about 36 nm, about 2 nm to about 35 nm, about 2 nm to about 34 nm, about 2 nm to about 33 nm, about 2 nm to about 32 nm, about 2 nm to about 31 nm, about 2 nm to about 30 nm, about 2 nm to about 29 nm, or about 2 nm to about 28 nm.

For example, the quantum dot may include a Group II-VI semiconductor compound, a Group III-V semiconductor compound, a Group IV-VI semiconductor compound, a Group IV semiconductor element or compound, a Group semiconductor compound, a Group I-II-IV-VI semiconductor compound, a Group II-III-V semiconductor compound, or a combination thereof.

The Group II-VI semiconductor compound may be, for example, a binary element compound such as CdSe, CdTe, ZnS, ZnSe, ZnTe, ZnO, HgS, HgSe, HgTe, MgSe, MgS, or a mixture thereof; a ternary element compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or a mixture thereof; or a quaternary element compound such as HgZnTeS, CdZnSeS, CdZnSeTe, CdZnSTe, CdHgSeS, CdHgSeTe, CdHgSTe, HgZnSeS, HgZnSeTe, HgZnSTe, or a mixture thereof, but is not limited thereto. The Group III-V semiconductor compound may be, for example, a binary element compound such as GaN, GaP, GaAs, GaSb, AlN, AlP, AlAs, AlSb, InN, InP, InAs, InSb, or a mixture thereof; a ternary element compound such as GaNP, GaNAs, GaNSb, GaPAs, GaPSb, AlNP, AlNAs, AlNSb, AlPAs, AlPSb, InNP, InNAs, InNSb, InPAs, InPSb, or a mixture thereof; or a quaternary element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a mixture thereof, but is not limited thereto. The Group IV-VI semiconductor compound may be, for example, a binary element compound such as SnS, SnSe, SnTe, PbS, PbSe, PbTe, or a mixture thereof; a ternary element compound such as SnSeS, SnSeTe, SnSTe, PbSeS, PbSeTe, PbSTe, SnPbS, SnPbSe, SnPbTe, or a mixture thereof; or a quaternary element compound such as SnPbSSe, SnPbSeTe, SnPbSTe, or a mixture thereof, but is not limited thereto. The Group IV semiconductor element or compound may be for example a single element semiconductor such as Si, Ge, or a mixture thereof; and a binary element semiconductor compound such as SiC, SiGe, or a mixture thereof, but is not limited thereto. The Group semiconductor compound may be, for example, CuInSe₂, CuInS₂, CuInGaSe, CuInGaS, or a mixture thereof, but is not limited thereto. The Group I-II-IV-VI semiconductor compound may be, for example, CuZnSnSe, CuZnSnS, or a mixture thereof, but is not limited thereto. The Group II-III-V semiconductor compound may be, for example, InZnP, but is not limited thereto.

The quantum dot may include a single element semiconductor, a binary semiconductor compound, a ternary semiconductor compound, or a quaternary semiconductor compound in a substantially uniform concentration, or at least one may be included in a state having a partially different concentration distribution.

For example, the quantum dot may include a cadmium (Cd)-free quantum dot. Cd may cause severe environment/health problems and a restricted element by Restriction of Hazardous Substances Directive (RoHS) in a plurality of countries, and thus the non-cadmium-based quantum dot may be effectively used. In an example, the light emitting layer 13 may not include cadmium. In an example, the light emitting layer 13 may not include cadmium, lead, mercury, or a combination thereof.

As an example, the quantum dot may be a semiconductor compound including zinc (Zn), and at least one of tellurium (Te) and selenium (Se). For example, the quantum dot may be a Zn—Te semiconductor compound, a Zn—Se semiconductor compound, and/or a Zn—Te—Se semiconductor compound. For example, a mole fraction of tellurium (Te) in the Zn—Te—Se semiconductor compound may be smaller than a mole fraction of selenium (Se). The semiconductor compound may have a maximum emission wavelength in a wavelength region of less than or equal to about 480 nm, for example, about 430 nm to about 480 nm, and may be configured to emit blue light.

For example, the quantum dot may be a semiconductor compound including indium (In) and at least one of zinc (Zn) and phosphorus (P). For example, the quantum dot may be an In—P semiconductor compound and/or an In—Zn—P semiconductor compound. For example, in the In—Zn—P semiconductor compound, a mole ratio of zinc (Zn) to indium (In) may be greater than or equal to about 25:1.

The quantum dot may have a core-shell structure wherein one quantum dot surrounds another quantum dot. For example, the core and the shell of the quantum dot may have an interface, and an element of at least one of the core or the shell in the interface may have a concentration gradient wherein the concentration of the element(s) of the shell decreases toward the core. For example, a material composition of the shell of the quantum dot has a higher energy bandgap than a material composition of the core of the quantum dot, and thereby the quantum dot may exhibit a quantum confinement effect.

The quantum dot may have one quantum dot core and a multilayered quantum dot shell surrounding the core. Herein, the multilayered shell has at least two shells wherein each shell may be a single composition, an alloy, and/or a shell having a concentration gradient.

For example, a shell of a multilayered shell that is far from (distal to) the core may have a higher energy bandgap than a shell that is near (more proximate) to the core, and thereby, the quantum dot may exhibit a quantum confinement effect.

For example, the quantum dot having a core-shell structure may for example include a core including a first semiconductor compound including zinc (Zn) and at least one of tellurium (Te) or selenium (Se), and a shell including a second semiconductor compound disposed on at least a portion of the core and having a different composition from that of the core.

For example, the first semiconductor compound may be a Zn—Te—Se-based semiconductor compound including zinc (Zn), tellurium (Te), and selenium (Se), for example, a Zn—Se-based semiconductor compound including a tellurium (Te), or a small amount of tellurium (Te), for example, a semiconductor compound represented by ZnTeₓSe₁₋ₓ, where x is greater than about 0 and less than or equal to 0.05.

For example, in the Zn—Te—Se-based first semiconductor compound, a mole fraction of zinc (Zn) may be higher than that of selenium (Se), and a mole fraction of selenium (Se) may be higher than that of tellurium (Te). For example, in the first semiconductor compound, a mole ratio of tellurium (Te) to selenium (Se) (or Te:SE) may be less than or equal to about 0.05:1, less than or equal to about 0.049:1, less than or equal to about 0.048:1, less than or equal to about 0.047:1, less than or equal to about 0.045:1, less than or equal to about 0.044:1, less than or equal to about 0.043:1, less than or equal to about 0.042:1, less than or equal to about 0.041:1, less than or equal to about 0.04:1, less than or equal to about 0.039:1, less than or equal to about 0.035:1, less than or equal to about 0.03:1, less than or equal to about 0.029:1, less than or equal to about 0.025:1, less than or equal to about 0.024:1, less than or equal to about 0.023:1, less than or equal to about 0.022:1, less than or equal to about 0.021:1, less than or equal to about 0.02:1, less than or equal to about 0.019:1, less than or equal to about 0.018:1, less than or equal to about 0.017:1, less than or equal to about 0.016:1, less than or equal to about 0.015:1, less than or equal to about 0.014:1, less than or equal to about 0.013:1, less than or equal to about 0.012:1, less than or equal to about 0.011:1, or less than or equal to about 0.01:1. For example, in the first semiconductor compound, a mole ratio of tellurium (Te) to zinc (Zn) may be less than or equal to about 0.02:1, less than or equal to about 0.019:1, less than or equal to about 0.018:1, less than or equal to about 0.017:1, less than or equal to about 0.016:1, less than or equal to about 0.015:1, less than or equal to about 0.014:1, less than or equal to about 0.013:1, less than or equal to about 0.012:1, less than or equal to about 0.011:1, or less than or equal to about 0.010:1.

The second semiconductor compound may include, for example, a Group II-VI semiconductor compound, a Group III-V semiconductor compound, a Group IV-VI semiconductor compound, a Group IV semiconductor element or compound, a Group semiconductor compound, a Group I-II-IV-VI semiconductor compound, a Group II-III-V semiconductor compound, or a combination thereof. Examples of the Group II-VI semiconductor compound, Group III-V semiconductor compound, Group IV-VI semiconductor compound, Group IV semiconductor element or compound, Group semiconductor compound, Group I-II-IV-VI semiconductor compound, and Group II-III-V semiconductor compound are the same as described above.

For example, the second semiconductor compound may include zinc (Zn), selenium (Se), and/or sulfur (S). For example, the shell may include ZnSeS, ZnS, or a combination thereof. For example, the shell may include at least one inner shell disposed closer (proximate) to the core and an outermost shell disposed as an outer or outermost layer of the quantum dot. The inner shell may include ZnSeS and the outermost shell may include ZnS. For example, the shell may have a concentration gradient of one component and for example a content of sulfur (S) may increase with distance from the core.

For example, a quantum dot having a core-shell structure may include a core including a third semiconductor compound including indium (In) and at least one of zinc (Zn) or phosphorus (P), and a shell disposed on at least a portion of the core and including a fourth semiconductor compound having a composition different from the core.

In the In—Zn—P-based third semiconductor compound, a mole ratio of zinc (Zn) to indium (In) (or Zn:In) may be greater than or equal to about 25:1. For example, in the In—Zn—P-based third semiconductor compound, the mole ratio of zinc (Zn) to indium (In) may be greater than or equal to about 28:1, greater than or equal to about 29:1, or greater than or equal to about 30:1. For example, in the In—Zn—P-based third semiconductor compound, the mole ratio of zinc (Zn) to indium (In) may be less than or equal to about 55:1, for example less than or equal to about 50:1, less than or equal to about 45:1, less than or equal to about 40:1, less than or equal to about 35:1, less than or equal to about 34:1, less than or equal to about 33:1, or less than or equal to about 32:1.

The fourth semiconductor compound may include, for example, a Group II-VI semiconductor compound, a Group III-V semiconductor compound, a Group IV-VI semiconductor compound, a Group IV semiconductor element or compound, a Group semiconductor compound, a Group I-II-IV-VI semiconductor compound, a Group II-III-V semiconductor compound, or a combination thereof. Examples of the Group II-VI semiconductor compound, Group III-V semiconductor compound, Group IV-VI semiconductor compound, Group IV semiconductor element or compound, Group semiconductor compound, Group I-II-IV-VI semiconductor compound, and Group II-III-V semiconductor compound are the same as described above.

For example, the fourth semiconductor compound may include zinc (Zn) and sulfur (S), and optionally, selenium (Se). For example, the shell may include ZnSeS, ZnS, or a combination thereof. For example, the shell may include at least one inner shell disposed proximate to the core and an outermost shell disposed as an outermost layer of the quantum dot. At least one of the inner shell and the outermost shell may include a fourth semiconductor compound of ZnS, or ZnSeS.

The aforementioned quantum dots are commercially available or may be appropriately synthesized.

In the quantum dot device 10 of an example, the quantum dot(s) may include a first organic ligand on the surface thereof. The first organic ligand may have a hydrophobic moiety. The first organic ligand may be bound to the surface of the quantum dot. The first organic ligand may include RCOOH, RNH₂, R₂NH, R₃N, RSH, R₃PO, R₃P, ROH, RCOOR, RPO(OH)₂, RHPOOH, R₂POOH, or a combination thereof, wherein R is each independently a substituted or unsubstituted C3 (or C5) to C40 aliphatic hydrocarbon group such as a substituted or unsubstituted C3 to C40 alkyl, alkenyl, etc., a substituted or unsubstituted C6 to C40 aromatic hydrocarbon group such as a substituted or unsubstituted C6 to C40 aryl group, etc., or a combination thereof.

Examples of the organic ligand may be a thiol compound such as methane thiol, ethane thiol, propane thiol, butane thiol, pentane thiol, hexane thiol, octane thiol, dodecane thiol, hexadecane thiol, octadecane thiol, benzyl thiol, and the like; amines such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, trioctylamine, and the like; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, and the like; a phosphine compound such as methyl phosphine, ethyl phosphine, propyl phosphine, butyl phosphine, pentyl phosphine, octylphosphine, dioctyl phosphine, tributylphosphine, trioctylphosphine, and the like; a phosphine compound or an oxide compound thereof such as methylphosphine oxide, ethylphosphine oxide, propylphosphine oxide, butylphosphine oxide, pentylphosphine oxide, tributylphosphine oxide, octylphosphine oxide, dioctylphosphine oxide, trioctylphosphine oxide; diphenyl phosphine, a triphenyl phosphine compound or an oxide compound thereof; a C5 to C20 alkylphosphinic acid such as hexylphosphinic acid, octylphosphinic acid, dodecanephosphinic acid, tetradecanephosphinic acid, hexadecanephosphinic acid, octadecanephosphinic acid; a C5 to C20 alkyl phosphonic acid such as hexylphosphonic acid, octylphosphonic acid, dodecanephosphonic acid, tetradecanephosphonic acid, hexadecanephosphonic acid, octadecanephosphonic acid; and the like, but are not limited thereto. The quantum dots may include a hydrophobic organic ligand alone or in a mixture of at least one (e.g., two or more) types.

The quantum dots may include a halogen together with an organic ligand (e.g., C5 or higher or C10 or higher fatty acid compound, e.g., oleic acid) on the surface (hereinafter, referred to as “halogen-treated quantum dots”). The content of halogen in halogen-treated quantum dots may be, for example, greater than or equal to about 1 microgram (ug), greater than or equal to about 1.5 ug, greater than or equal to about 3 ug, greater than or equal to about 4 ug, greater than or equal to about 5 ug, greater than or equal to about 6 ug, greater than or equal to about 7 ug, greater than or equal to about 8 ug, greater than or equal to about 9 ug, greater than or equal to about 10 ug, greater than or equal to about 11 ug, greater than or equal to about 12 ug, greater than or equal to about 12.5 ug, greater than or equal to about 13 ug, greater than or equal to about 14 ug, greater than or equal to about 15 ug, greater than or equal to about 16 ug, greater than or equal to about 17 ug, greater than or equal to about 18 ug, or greater than or equal to about 19 ug and less than about 30 ug, less than or equal to about 25 ug, less than or equal to about 20 ug, less than or equal to about 19.5 ug, less than or equal to about 19 ug, less than or equal to about 18 ug, less than or equal to about 17 ug, less than or equal to about 15 ug, less than or equal to about 12.5 ug, or less than or equal to about 12 ug, each per milligram (mg) of quantum dots, which may be determined, for example, by ion chromatography. The halogen may be chlorine.

An example of a method of preparing the halogen-treated quantum dots may include obtaining an organic dispersion including a plurality of quantum dots including a first organic ligand on the surface and a first organic solvent; obtaining a halide, e.g., a chloride solution including a polar organic solvent miscible with the first organic solvent and a metal halide, e.g., a metal chloride; and adding the halide, e.g., chloride solution to the organic dispersion so that the content of the metal halide, e.g., metal chloride is greater than or equal to about 0.1 weight percent (wt %) and less than or equal to about 10 wt % based on the total weight of the quantum dots, and then stirring the resultant mixture at a temperature of greater than or equal to about 45° C., for example, greater than or equal to about 50° C., greater than or equal to about 55° C., or greater than or equal to about 60° C. and less than or equal to about 150° C., less than or equal to about 140° C., less than or equal to about 100° C., less than or equal to about 90° C., less than or equal to about 80° C., or less than or equal to about 70° C. A volume ratio of the polar organic solvent to the first organic solvent may be less than or equal to about 0.1:1.

The metal halide (e.g., metal chloride) may include a zinc halide, an indium halide, a gallium halide, a magnesium halide, a lithium halide, or a combination thereof. The first organic solvent may include a substituted or unsubstituted C5 to C40 aliphatic hydrocarbon, a substituted or unsubstituted C6 to C40 aromatic hydrocarbon, a substituted or unsubstituted C3 to C40 alicyclic hydrocarbon, or a combination thereof. The polar organic solvent may include a C1 to C10 alcohol (e.g., methanol, ethanol, propanol, isopropanol, butanol, pentanol, hexanol, heptanol, etc.) or a combination thereof.

The light emitting layer 13 may have a single layer or a multilayer structure in which two or more layers are stacked. In the multilayer structure, adjacent layers (e.g., the first light emitting layer and the second light emitting layer) may have different physical properties/compositions. At least one of the light emitting layers 13 of an example may further include a halogen (e.g., chlorine). The light emitting layer 13 of an example may exhibit a halogen content that changes along a thickness direction.

The light emitting layer 13 of an example may exhibit a carbon content that varies along a thickness direction. In an example of the light emitting layer 13, the carbon content may increase in a region approaching a second hole auxiliary layer 15. In an example of the light emitting layer 13, the carbon content may decrease in a region approaching the second hole auxiliary layer 15.

An example of the light emitting layer 13 may include a layer (hereinafter, referred to as a surface-treated first light emitting layer or a first layer) including quantum dots and having a surface treated with halogen (e.g., chlorine). A second layer including the halogen-treated quantum dots and/or a third layer including quantum dots having organic ligands may be disposed on the first layer. The second layer may be disposed between the first layer and the third layer. The organic material (e.g., carbon) content (e.g., concentration) of the first layer may be lower than the organic material content of the second layer. The halogen (e.g., chlorine) content (e.g., concentration) of the first layer may be higher than the halogen content of the second layer. The organic material content of the first layer may be higher than the organic material content of the second layer. The halogen content of the first layer may be lower than the organic material content of the second layer. The organic material content of the light emitting layer 13 may be controlled by an appropriate means (post-treatment for the formed layer).

The light emitting layer 13 may have a relatively deep HOMO energy level, for example, a HOMO energy level of greater than or equal to about 5.4 electron Volts (eV), for example greater than or equal to about 5.6 eV, within the range, for example greater than or equal to about 5.7 eV, for example greater than or equal to about 5.8 eV, for example greater than or equal to about 5.9 eV, for example greater than or equal to about 6.0 eV. The HOMO energy level of the light emitting layer 13 may be, within a range, for example, about 5.4 eV to about 7.0 eV, for example, about 5.4 eV to about 6.8 eV, for example, about 5.4 eV to about 6.7 eV, for example, about 5.4 eV to about 6.5 eV, for example, about 5.4 eV to about 6.3 eV, for example, about 5.4 eV to about 6.2 eV, for example, about 5.4 eV to about 6.1 eV, within the above range, for example, about 5.6 eV to about 7.0 eV, for example, about 5.6 eV to about 6.8 eV, for example, about 5.6 eV to about 6.7 eV, for example, about 5.6 eV to about 6.5 eV, for example, about 5.6 eV to about 6.3 eV, for example, about 5.6 eV to about 6.2 eV, for example, about 5.6 eV to about 6.1 eV, within the above range, for example, about 5.7 eV to about 7.0 eV, for example, about 5.7 eV to about 6.8 eV, for example, about 5.7 eV to about 6.7 eV, for example, about 5.7 eV to about 6.5 eV, for example, about 5.7 eV to about 6.3 eV, for example, about 5.7 eV to about 6.2 eV, for example, about 5.7 eV to about 6.1 eV, within the above range, for example, about 5.8 eV to about 7.0 eV, for example, about 5.8 eV to about 6.8 eV, for example, about 5.8 eV to about 6.7 eV, for example, about 5.8 eV to about 6.5 eV, for example, about 5.8 eV to about 6.3 eV, for example, about 5.8 eV to about 6.2 eV, for example, about 5.8 eV to about 6.1 eV, within the above range, for example, about 6.0 eV to about 7.0 eV, for example, about 6.0 eV to about 6.8 eV, for example, about 6.0 eV to about 6.7 eV, for example, about 6.0 eV to about 6.5 eV, for example, about 6.0 eV to about 6.3 eV, for example, about 6.0 eV to about 6.2 eV.

The light emitting layer 13 may have a relatively shallow LUMO energy level, for example, less than or equal to about 3.6 eV, for example, less than or equal to about 3.5 eV, for example, less than or equal to about 3.4 eV, for example, less than or equal to about 3.3 eV, for example, less than or equal to about 3.2 eV, or for example, less than or equal to about 3.0 eV. Within the range, the LUMO energy level of the light emitting layer 13 may be about 2.5 eV to about 3.6 eV, about 2.5 eV to about 3.5 eV, for example, about 2.5 eV to about 3.4 eV, for example, about 2.5 eV to about 3.3 eV, for example, about 2.5 eV to about 3.2 eV, for example, about 2.5 eV to about 3.1 eV, for example, about 2.5 eV to about 3.0 eV, for example, about 2.8 eV to about 3.6 eV, about 2.8 eV to about 3.5 eV, for example, about 2.8 eV to about 3.4 eV, for example, about 2.8 eV to about 3.3 eV, for example, about 2.8 eV to about 3.2 eV, about 3.0 eV to about 3.6 eV, about 3.0 eV to about 3.5 eV, or for example, about 3.0 eV to about 3.4 eV.

The light emitting layer 13 may have an energy bandgap of about 2.4 eV to about 2.9 eV. Within the above range, the light emitting layer 13 may have an energy bandgap, for example, about 2.4 eV to about 2.8 eV, within the above range, for example, about 2.4 eV to about 2.78 eV.

A thickness of the light emitting layer 13 may be less than or equal to about 200 nm, for example, about 5 nm to about 200 nm, about 10 nm to about 200 nm, about 20 nm to about 150 nm, about 20 nm to about 100 nm, about 30 nm to about 100 nm, about 20 nm to about 80 nm, or about 30 nm to about 80 nm.

The first hole auxiliary layer 14 and the second hole auxiliary layer 15 may be functional layers that are disposed between the first electrode 11 and the light emitting layer 13 to improve electrical performance between the first electrode 11 and the light emitting layer 13.

For example, the first hole auxiliary layer 14 may be proximate to the first electrode 11 and disposed between the first electrode 11 and the light emitting layer 13, and the second hole auxiliary layer 15 may be proximate to the light emitting layer 13 and disposed between the first electrode 11 and the light emitting layer 13. For example, the first hole auxiliary layer 14 may be in contact with the first electrode 11 and the second hole auxiliary layer 15 may be in contact with the light emitting layer 13.

The first hole auxiliary layer 14 and the second hole auxiliary layer 15 may increase the efficiency of injection and transport of holes from the first electrode 11 to the light emitting layer 13. For example, the first hole auxiliary layer 14 may be a hole injection layer that increases the injection efficiency of holes from the first electrode 11 and the second hole auxiliary layer 15 may be a hole transport layer that increases the transport efficiency of holes to the light emitting layer 13. At least one of the first hole auxiliary layer 14 or the second hole auxiliary layer 15 may have electron blocking characteristics.

The first hole auxiliary layer 14 and the second hole auxiliary layer 15 may have a relatively high HOMO energy level to match the HOMO energy level of the light emitting layer 13. Accordingly, the mobility of holes transmitted to the light emitting layer 13 from the first electrode 11 through the first hole auxiliary layer 14 and the second hole auxiliary layer 15 may be increased.

The HOMO energy levels of the first hole auxiliary layer 14 and the second hole auxiliary layer 15 may be equal to or smaller than the HOMO energy level of the light emitting layer 13 and within a range of less than or equal to about 1.0 eV. For example, a difference between the HOMO energy level of the second hole auxiliary layer 15 and the light emitting layer 13 may be about 0 eV to about 1.0 eV, for example about 0.01 eV to about 0.8 eV, within the above range, for example about 0.01 eV to about 0.7 eV, within the above range, for example about 0.01 eV to about 0.5 eV, within the above range, for example about 0.01 eV to about 0.4 eV, for example about 0.01 eV to about 0.3 eV, for example about 0.01 eV to about 0.2 eV, for example about 0.01 eV to about 0.1 eV.

The HOMO energy level of the first hole auxiliary layer 14 and the second hole auxiliary layer 15 may be, for example, greater than or equal to about 5.0 eV, for example, greater than or equal to about 5.2 eV, for example, greater than or equal to about 5.4 eV, for example, greater than or equal to about 5.6 eV, or for example greater than or equal to about 5.8 eV.

For example, the HOMO energy level of the first hole auxiliary layer 14 and the second hole auxiliary layer 15 may be about 5.0 eV to about 7.0 eV, within the above range, for example about 5.2 eV to about 6.8 eV, within the above range, for example about 5.4 eV to about 6.8 eV, for example about 5.4 eV to about 6.7 eV, for example about 5.4 eV to about 6.5 eV, for example about 5.4 eV to about 6.3 eV, for example about 5.4 eV to about 6.2 eV, for example about 5.4 eV to about 6.1 eV, for example about 5.6 eV to about 7.0 eV, for example about 5.6 eV to about 6.8 eV, for example about 5.6 eV to about 6.7 eV, for example about 5.6 eV to about 6.5 eV, for example about 5.6 eV to about 6.3 eV, for example about 5.6 eV to about 6.2 eV, for example about 5.6 eV to about 6.1 eV, for example about 5.8 eV to about 7.0 eV, for example about 5.8 eV to about 6.8 eV, for example about 5.8 eV to about 6.7 eV, for example about 5.8 eV to about 6.5 eV, for example about 5.8 eV to about 6.3 eV, for example about 5.8 eV to about 6.2 eV, or for example about 5.8 eV to about 6.1 eV.

The first hole auxiliary layer 14 and the second hole auxiliary layer 15 may include one or more hole transport materials, and the hole transport materials may include, for example, 4-methoxyphenyl)-benzidine (TPD), N,N′-bis(1-naphthyl)-N,N′-diphenyl-(1,1′-biphenyl)-4,4′-diamine (NPD), 4,4′,4″-tris[phenyl(m-tolyl)amino]triphenylamine) (m-MTDATA), 4,4′,4″-tris(N-carbazolyl)-triphenylamine (TCTA), 1,1-bis[(di-4-tolylamino)phenyl]cyclohexane (TAPC), N2,N7-di(naphthalen-1-yl)-9,9-dioctyl-N2,N7-diphenyl-9H-fluorene-2,7-diamine (NPB), 2,7-bis(carbazol-9-yl)-9,9-spirobifluorene (Spiro-2CBP), 2,2′,7,7′-tetra(N,N-di-p-tolyl)amino-9,9-spirobifluorene (Spiro-TTB), 2,2′,7,7′-tetrakis(N,N-diphenylamino)-9,9-spirobifluorene (Spiro-TAD), 1,1-bis[(di-4-tolylamino)phenyl]cyclohexane (TAPC), 4,4′-bis(N-carbazolyl)-1,1′-biphenyl (CBP), 4,4′,4″-tris[2-naphthyl(phenyl)amino]triphenylamine (2-TNATA), 1,3,5-tris (4-diphenylaminophenyl)benzene (TDAPB), poly(9,9-dioctyl-fluorene-co-N-(4-butylphenyl)-diphenylamine) (TFB), polyarylamine, poly(N-vinylcarbazole) (poly(N-vinylcarbazole), poly(3,4-ethylenedioxythiophene (PEDOT), poly(3,4-ethylenedioxythiophene)polystyrene sulfonate (PEDOT:PSS), polyaniline, polypyrrole, Spiro-PMATD, triphenylbismuth dichloride (TPBC), poly(triaryl amine) (PTAA), poly (3-hexylthiophene-2,5-diyl) (P3HT), poly[3-(5-carboxypentyl)thiophene-2,5-diyl] (P3CPenT), poly[2,6-(4,4-bis-(2-ethylhexyl)-4H-cyclopenta[2,1-b;3,4-b′]dithiophene)-alt-4,7(2,1,3-benzothiadiazole)] (PCPDT-t), poly(2,3-dihydrothieno[3,4-b][1,4]dioxane-5,7-diyl) (PEDOT-S), polyferric sulfate (PFS), CuI, Cu₂O, CuO, CuS, NiOₓ, CuGaO₂, CuPc, CuSCN, MoOₓ, MoS₂, VOₓ, CoOₓ, graphene oxide, or a combination thereof, but is not limited thereto.

The first electron auxiliary layer 16a, the second electron auxiliary layer 16b, and the insertion layer 16c may be functional layers for improving electrical performance between the second electrode 12 and the light emitting layer 13. They may increase transport efficiency of electrons from the second electrode 12 to the light emitting layer 13 and may also block the injection of holes from the light emitting layer 13 to the second electrode 12.

The first electron auxiliary layer 16a may be proximate to the light emitting layer 13 and disposed between the second electrode 12 and the light emitting layer 13, and the second electron auxiliary layer 16b may be proximate to the second electrode 12 and disposed between the second electrode 12 and the light emitting layer 13. For example, the first electron auxiliary layer 16a may be in contact with the emission layer 13, and the second electron auxiliary layer 16b may be in contact with the second electrode 12.

The first electron auxiliary layer 16a and the second electron auxiliary layer 16b may include the same or different electron auxiliary material, and the electron auxiliary material may be an electron transport material and/or an electron injection material. For example, the first electron auxiliary layer 16a may include a first electron auxiliary material and the second electron auxiliary layer 16b may include a second electron auxiliary material. The first electron auxiliary material and the second electron auxiliary material may be the same or different.

The LUMO energy level of the first electron auxiliary material and the second electron auxiliary material may be deeper or shallower than the LUMO energy level of the light emitting layer 13 (quantum dots included in the light emitting layer), and for example, may be deeper. A difference between the LUMO energy level of the first electron auxiliary material/second electron auxiliary material and the LUMO energy level of the light emitting layer 13 (quantum dots included in the light emitting layer) may be less than or equal to about 2.5 eV, less than or equal to about 2.3 eV, less than or equal to about 2.0 eV, or less than or equal to about 1.8 eV. The LUMO energy levels of the first electron auxiliary material and the second electron auxiliary material may be, for example, about 2.5 eV to about 4.8 eV, respectively, or within the above range, for example, about 2.6 eV to about 4.6 eV, or about 2.7 eV to about 4.5 eV.

The HOMO energy levels of the first electron auxiliary material and the second electron auxiliary material may be deeper than the HOMO energy level of the light emitting layer 13 (quantum dots included in the light emitting layer). For example, the HOMO energy level of the first electron auxiliary material/second electron auxiliary material may be deeper than the HOMO energy level of the light emitting layer 13 (quantum dots included in the light emitting layer) by greater than or equal to about 0.2 eV, greater than or equal to about 0.5 eV, greater than or equal to about 0.8 eV, greater than or equal to about 1.0 eV, greater than or equal to about 1.2 eV, or greater than or equal to about 1.5 eV, for example, about 0.2 eV to about 3.0 eV, about 0.5 eV to about 3.0 eV, about 0.8 eV to about 3.0 eV, about 1.0 eV to about 3.0 eV, about 1.2 eV to about 3.0 eV, or about 1.5 eV to about 3.0 eV.

For example, the HOMO energy levels of the first electron auxiliary material and the second electron auxiliary material may be, for example, about 5.6 eV to about 8.5 eV, within the range, about 5.8 eV to about 8.2 eV, about 6.0 eV to about 8.0 eV, about 6.2 eV to about 8.0 eV, about 6.5 eV to about 8.0 eV, about 6.8 eV to about 8.0 eV, about 7.0 eV to about 8.0 eV, about 7.2 eV to about 7.9 eV, or about 7.3 eV to about 7.8 eV.

For example, an energy bandgap of the first electron auxiliary material and the second electron auxiliary material may be greater than or equal to about 2.0 eV and less than about 4.0 eV, or within the above range, about 2.1 eV to about 3.9 eV, about 2.3 eV to about 3.8 eV, or about 2.5 eV to about 3.8 eV.

For example, at least one of the first electron auxiliary material and the second electron auxiliary material may include inorganic nanoparticles (hereinafter referred to as “first inorganic nanoparticles”), and the first inorganic nanoparticles may be, for example, oxide nanoparticles, for example, metal oxide nanoparticles. For example, each of the first electron auxiliary material and the second electron auxiliary material may include first inorganic nanoparticles, and the first inorganic nanoparticles may be, for example, oxide nanoparticles, such as metal oxide nanoparticles. For example, the first inorganic nanoparticles may be metal oxide nanoparticles including two or more types of metals. For example, the first inorganic nanoparticles may be inorganic semiconductors, for example, n-type inorganic nanoparticles.

The first inorganic nanoparticles may be two-dimensional or three-dimensional nanoparticles having an average particle diameter of less than about 10 nm, less than or equal to about 8 nm, less than or equal to about 7 nm, less than or equal to about 6 nm, less than or equal to about 5 nm, less than or equal to about 4 nm, or less than or equal to about 3.5 nm, or within a range, greater than or equal to about 1 nm and less than about 10 nm, about 1 nm to about 9 nm, about 1 nm to about 8 nm, about 1 nm to about 7 nm, about 1 nm to about 6 nm, about 1 nm to about 5 nm, about 1 nm to about 4 nm, or about 1 nm to about 3.5 nm.

The HOMO energy level of the first inorganic nanoparticles may be the same as the HOMO energy level of the aforementioned first electron auxiliary material and second electron auxiliary material and may be, for example, about 5.6 eV to about 8.5 eV, about 5.8 eV to about 8.2 eV, about 6.0 eV to about 8.0 eV, about 6.2 eV to about 8.0 eV, about 6.5 eV to about 8.0 eV, about 6.8 eV to about 8.0 eV, about 7.0 eV to about 8.0 eV, about 7.2 eV to about 7.9 eV, or about 7.3 eV to about 7.8 eV.

The LUMO energy level of the first inorganic nanoparticles may be the same as the LUMO energy levels of the aforementioned first electron auxiliary material and second electron auxiliary material, and may be, for example, about 2.5 eV to about 4.8 eV, about 2.6 eV to about 4.6 eV, or about 2.7 eV to about 4.5 eV.

The energy bandgap of the first inorganic nanoparticles may be the same as the energy bandgaps of the aforementioned first electron auxiliary material and second electron auxiliary material, and may be, for example, greater than or equal to about 2.0 eV and less than about 4.0 eV, about 2.1 eV to about 3.9 eV, about 2.3 eV to about 3.8 eV, or about 2.5 eV to about 3.8 eV.

The first inorganic nanoparticles may be materials satisfying the above-described energy level, and may be, for example, metal oxide nanoparticles including at least one of zinc (Zn), magnesium (Mg), cobalt (Co), nickel (Ni), gallium (Ga), aluminum (Al), calcium (Ca), zirconium (Zr), tungsten (W), lithium (Li), titanium (Ti), tantalum (Ta), tin (Sn), or barium (Ba).

For example, the first inorganic nanoparticles may include metal oxide nanoparticles including zinc (Zn), for example, metal oxide nanoparticles expressed as Zn₁₋ₓQₓO (0≤x<0.5). Here, Q may include one or more metals other than Zn, such as magnesium (Mg), cobalt (Co), nickel (Ni), gallium (Ga), aluminum (Al), calcium (Ca), zirconium (Zr), W), lithium (Li), titanium (Ti), tantalum (Ta), tin (Sn), hafnium (Hf), silicon (Si), barium (Ba), or a combination thereof.

For example, Q may include magnesium (Mg).

For example, x may satisfy the range of 0.01≤x≤0.4, 0.01≤x≤0.3, or 0.01≤x≤0.2.

The first electron auxiliary material and the second electron auxiliary material may further include an alkali metal, an alkali metal compound, or a combination thereof in addition to the first inorganic nanoparticles. The alkali metal, alkali metal compound, or combination thereof may be included in the form of a mixture with the first inorganic nanoparticles described above and may be included in a limited amount in the first electron auxiliary layer 16a and the second electron auxiliary layer 16b to effectively improve the electrical characteristics of the first electron auxiliary layer 16a and the second electron auxiliary layer 16b.

The alkali metal, alkali metal compound, or combination thereof may be included in the form of, for example, an alkali metal cation, an alkali metal cation derived from an alkali metal compound, or a combination thereof. The alkali metal compound may be a compound including an alkali metal, for example, alkali carbonate, alkali phosphate, alkali vanadate, alkali azide, alkali nitride, or a combination thereof.

The alkali metal or alkali metal included in the alkali metal compound may be, for example, lithium (Li), sodium (Na), potassium (K), cesium (Cs), rubidium (Rb), francium (Fr) or a combination thereof. These lithium (Li), sodium (Na), potassium (K), cesium (Cs), rubidium (Rb), or francium (Fr) may be included in a form of a lithium cation, a sodium cation, a potassium cation, a cesium cation, a rubidium cation, or a francium cation, respectively.

The alkali metal compound (e.g., alkali metal salt) may further include an anion such as carbonate (CO₃²⁻), phosphate (PO₄³⁻), vanadate (VO₄³⁻), azide (N₃⁻), or nitride (N³⁻), together with the alkali metal cation.

For example, the alkali metal may be lithium (Li), sodium (Na), potassium (K), cesium (Cs), rubidium (Rb), francium (Fr), or a combination thereof, and the alkali metal compound may be cesium carbonate (Cs₂CO₃), cesium phosphate (Cs₃PO₄), cesium vanadate (Cs₃VO₄), cesium azide (CsN₃), lithium carbonate (LiCO₃), lithium nitride (Li₃N), sodium carbonate (Na₂CO₃), potassium carbonate (K₂CO₃), rubidium carbonate (Rb₂CO₃), or a combination thereof, but is not limited thereto.

In the first electron auxiliary layer 16a and the second electron auxiliary layer 16b, the total alkali metal derived from the alkali metal, alkali metal compound, or combination thereof may be included in an amount of less than the first inorganic nanoparticles. For example, the total alkali metal derived from the alkali metal, alkali metal compound, or combination thereof may be included in an amount of about 0.1 volume percent (vol %) to about 30 vol %, within the above range, about 0.1 vol % to about 25 vol %, about 0.1 vol % to about 20 vol %, about 0.5 vol % to about 18 vol %, about 1 vol % to about 15 vol %, or about 3 vol % to about 15 vol % based on each of the first electron auxiliary layer 16a and the second electron auxiliary layer 16b. For example, the total alkali metal derived from the alkali metal, alkali metal compound, or combination thereof may be included in an amount of less than about 0.5 at % based on the total number of atoms included in each of the first electron auxiliary layer 16a and the second electron auxiliary layer 16b.

For example, the first electron auxiliary material and the second electron auxiliary material may be the same material, for example, and both include the first inorganic nanoparticles, for example, metal oxide nanoparticles represented by Zn₁₋ₓQₓO (0≤x<0.5), for example, the metal oxide nanoparticles represented by Zn₁₋ₓQₓO (0≤x<0.5) and alkali metal, an alkali metal compound, or a combination thereof.

The total sum thickness of the first electron auxiliary layer 16a and the second electron auxiliary layer 16b may be about 80 nm or less, for example, about 5 nm to about 80 nm, about 10 nm to about 80 nm, about 15 nm to about 60 nm, or about 20 nm to about 50 nm. For example, the thickness of second electron auxiliary layer 16b may be greater than the thickness of the first electron auxiliary layer 16a, for example, the thickness of second electron auxiliary layer 16b may be 2-times or more greater than the thickness of the first electron auxiliary layer 16a and within the above range, about 2-times to about 10-times greater than the thickness of the first electron auxiliary layer 16a.

The insertion layer 16c is disposed between the first electron auxiliary layer 16a and the second electron auxiliary layer 16b. One surface of the insertion layer 16c may be in contact with the first electron auxiliary layer 16a and the opposite surface of the insertion layer 16c may be in contact with the second electron auxiliary layer 16b.

The insertion layer 16c may include an inorganic material, and the inorganic material included in the insertion layer 16c may have stronger electrically insulating characteristics than the first electron auxiliary material included in the first electron auxiliary layer 16a and the second electron auxiliary material included in the second electron auxiliary layer 16b. For example, the inorganic material included in the insertion layer 16c may have a larger energy bandgap than the first electron auxiliary material included in the first electron auxiliary layer 16a and the second electron auxiliary material included in the second electron auxiliary layer 16b. For example, the energy bandgap of the inorganic material may be greater than or equal to about 4.5 eV, or deeper by within a range of about 4.5 eV to 10.0 eV, about 5.0 eV to 10.0 eV, about 5.5 eV to 10.0 eV, about 6.0 eV to 10.0 eV, about 6.5 eV to 10 eV, or about 7.0 eV to 10.0 eV.

The inorganic material included in the insertion layer 16c may have stronger hole-blocking characteristics than the first electron auxiliary material included in the first electron auxiliary layer 16a and the second electron auxiliary material included in the second electron auxiliary layer 16b. For example, the inorganic material of the insertion layer 16c may have a deeper HOMO energy level than the first electron auxiliary material included in the first electron auxiliary layer 16a and the second electron auxiliary material included in the second electron auxiliary layer 16b, for example, deeper by greater than or equal to about 0.1 eV, greater than or equal to about 0.2 eV, greater than or equal to about 0.3 eV, or greater than or equal to about 0.5 eV, and within a range of, about 0.1 eV to about 5.0 eV, about 0.2 eV to about 5.0 eV, about 0.3 eV to about 5.0 eV, or about 0.5 eV to about 5.0 eV.

For example, on the premise that the HOMO energy level of the inorganic material included in the insertion layer 16c is deeper than those of the first electron auxiliary material and the second electron auxiliary material, the HOMO energy level of the inorganic material included in the insertion layer 16c may be about 6.0 eV to about 12 eV, about 6.5 eV to about 12 eV, about 7.0 eV to about 12 eV, about 7.5 eV to about 12 eV, about 8.0 eV to about 12 eV, or about 8.5 eV to about 12 eV.

A LUMO energy level of the inorganic material included in the insertion layer 16c may be equal to or shallower than each LUMO energy level of the first electron auxiliary material and the second electron auxiliary material, for example, about 1.5 eV to about 4.5 eV, and within the above range, about 2.0 eV to about 4.3 eV, about 2.0 eV to about 4.0 eV, about 2.0 eV to about 3.5 eV, or about 2.0 eV to about 3.0 eV.

The inorganic material included in the insertion layer 16c may be inorganic nanoparticles satisfying the aforementioned energy bandgap and/or energy level (hereinafter, referred to as “second inorganic nanoparticles”), and the second inorganic nanoparticles of the insertion layer may be, for example, oxide nanoparticles, for example, (semi)metal oxide nanoparticles. For example, the second inorganic nanoparticles of the insertion layer may be non-conductive nanoparticles and non-semiconductive nanoparticles, for example, insulating nanoparticles.

The second inorganic nanoparticles of the insertion layer may be two-dimensional or three-dimensional nanoparticles having an average particle diameter of less than about 10 nm, less than or equal to about 8 nm, less than or equal to about 7 nm, less than or equal to about 6 nm, less than or equal to about 5 nm, less than or equal to about 4 nm, or less than or equal to about 3.5 nm, or within a range of, greater than or equal to about 1 nm and less than about 10 nm, about 1 nm to about 9 nm, about 1 nm to about 8 nm, about 1 nm to about 7 nm, about 1 nm to about 6 nm, about 1 nm to about 5 nm, about 1 nm to about 4 nm, greater than or equal to about 3 nm and less than about 10 nm, about 3 nm to about 9 nm, about 3 nm to about 8 nm, about 3 nm to about 7 nm, about 3 nm to about 6 nm, about 3 nm to about 5 nm, greater than or equal to about 4 nm and less than about 10 nm, about 4 nm to about 9 nm, about 4 nm to about 8 nm, about 4 nm to about 7 nm, or about 4 nm to about 6 nm.

The energy bandgap of the second inorganic nanoparticles of the insertion layer may be the same as the energy bandgap of the inorganic material, and for example, may be greater than or equal to about 4.5 eV, or within a range of, about 4.5 eV to about 10.0 eV, about 5.0 eV to about 10.0 eV, about 5.5 eV to about 10.0 eV, about 6.0 eV to about 10.0 eV, about 6.5 eV to about 10.0 eV, or about 7.0 eV to about 10.0 eV.

The HOMO energy level of the second inorganic nanoparticles of the insertion layer may be the same as the HOMO energy level of the aforementioned inorganic material, and for example, the HOMO energy level of the first electron auxiliary material and the second electron auxiliary material (first inorganic nanoparticles) may be deeper by greater than or equal to about 0.1 eV, greater than or equal to about 0.2 eV, greater than or equal to about 0.3 eV, or greater than or equal to about 0.5 eV, or within a range of, about 0.1 eV to about 5.0 eV, about 0.2 eV to about 5.0 eV, about 0.3 eV to about 5.0 eV, or about 0.5 eV to about 5.0 eV. The HOMO energy level of the second inorganic nanoparticles of the insertion layer may be about 6.0 eV to about 12.0 eV, about 6.5 eV to about 12.0 eV, about 7.0 eV to about 12.0 eV, about 7.5 eV to about 12.0 eV, about 8.0 eV to about 12.0 eV, or about 8.5 eV to about 12.0 eV.

The LUMO energy level of the second inorganic nanoparticles of the insertion layer may be the same as the LUMO energy level of the aforementioned inorganic material, and may be, for example, equal to or shallower than the LUMO energy level of the first electron auxiliary material and the second electron auxiliary material (e.g., first inorganic nanoparticles). The LUMO energy level of the inorganic nanoparticles of the insertion layer may be about 1.5 eV to about 4.5 eV, about 2.0 eV to about 4.3 eV, about 2.0 eV to about 4.0 eV, about 2.0 eV to about 3.5 eV, or about 2.0 eV to about 3.0 eV.

The second inorganic nanoparticles of the insertion layer may be selected from materials satisfying the aforementioned energy bandgap and energy level, for example, (semi)metal oxide nanoparticles including Si, Al, Zr, Mg, Ca, Hf, Y, La, or a combination thereof. For example, the second inorganic nanoparticles may be silica, alumina, zirconia, or a combination thereof, for example, silica.

The insertion layer 16c includes an inorganic material (second inorganic nanoparticle) having the aforementioned properties and may block excess holes not recombined in the light emitting layer 13 from passing through the first electron auxiliary layer 16a and reaching the second electron auxiliary layer 16b, and thereby, minimize performance deterioration of the quantum dot device 10.

In accordance with an embodiment, holes that do not combine with electrons/quantum dot (or excess holes) in the light emitting layer 13 may pass through the light emitting layer 13 and enter the first electron auxiliary layer 16a through trap sites of the first electron auxiliary layer 16a (e.g., at a similar energy level to the HOMO energy level of the light emitting layer 13). The trap sites of the first electron auxiliary layer 16a may be formed due to various reasons, for example, unavoidable defects formed during the synthesis of the first inorganic nanoparticles of the first electron auxiliary layer 16a or dangling bonds on the surfaces of the first inorganic nanoparticles, and accordingly, a plurality of the excess holes may be trapped in these defects and/or the dangling bonds.

If however, the insertion layer 16c is not present, the excess holes introduced into the first electron auxiliary layer 16a may accumulate in the trap sites, and thereby, generate a significant amount of leakage current, or pass through the first electron auxiliary layer 16a and into the second electron auxiliary layer 16b to generate a leakage of electric charges, which resultantly may generate a high leakage current and deteriorate a life-span.

Accordingly, the insertion layer 16c may effectively block migration of the excess holes and thus effectively reduce the leakage current and minimize the deterioration of a life-span.

The insertion layer 16c may be a nanolayer with a relatively thin thickness of less than about 10 nm, for example about 1 nm to about 9 nm, about 1 nm to about 8 nm, about 1 nm to about 6 nm, about 1 nm to about 5 nm, about 2 nm to about 9 nm, about 2 nm to about 8 nm, about 2 nm to about 6 nm, about 2 nm to about 5 nm, about 3 nm to about 9 nm, about 3 nm to about 8 nm, about 3 nm to about 6 nm, or about 3 nm to about 5 nm. Because the insertion layer 16c has a relatively thin thickness as described above, electrons moving from the second electrode 12 to the light emitting layer 13 may easily move though the insertion layer 16c due to tunneling effects. and thus, the insertion layer may have no influence on electron transport properties.

As described above, the quantum dot device 10 according to an embodiment has a structure that the first electron auxiliary layer 16a, the insertion layer 16c, and the second electron auxiliary layer 16b are sequentially disposed from the light emitting layer 13 to the second electrode 12, and thus, may block or reduce the leakage current by blocking the excess holes in the light emitting layer from passing through the first electron auxiliary layer 16a and the second electron auxiliary layer 16b and effectively prevent or reduce performance deterioration of the quantum dot device 10.

If however, the insertion layer 16c is disposed not between the first electron auxiliary layer 16a and the second electron auxiliary layer 16b, but instead, between the light emitting layer 13 and the first electron auxiliary layer 16a, the excess holes in the light emitting layer 13 may accumulate at the interface of the light emitting layer 13 and the insertion layer 16c (due to a high energy barrier of the insertion layer 16c). As a result, the accumulated excess holes at the interface between the light emitting layer 13 and the insertion layer 16c may be abnormally combined with the electrons moving from the second electrode 12 to the light emitting layer 13 at the interface, and thus generate non-emission excitons. Moreover, the excess hole and/or non-emission excitons may negatively affect the interface of the light emitting layer 13 and become a leakage path of the quantum dot device 10, which in turn, may eventually deteriorate life-span characteristics and electrical characteristics of the quantum dot device 10.

Therefore, in the quantum dot device 10 according to the present embodiment, the insertion layer 12c is not in direct contact with the light emitting layer 13, but instead, is interposed (inserted) between the first electron auxiliary layer 16a and the second electron auxiliary layer 16b, thereby effectively preventing or minimizing (slowing down) the degradation of performance of the aforementioned quantum dot device 10.

The insertion layer 16c may be positioned proximate to the light emitting layer 13 between the light emitting layer 13 and the second electrode 12. For example, the thickness of the second electron auxiliary layer 16b may be greater than the thickness of the first electron auxiliary layer 16a.

For example, the thickness of the first electron auxiliary layer 16a may be the same as or greater than the thickness of the insertion layer 16c, and the thickness of the second electron auxiliary layer 16b may be greater than the thickness of the first electron auxiliary layer 16a and the thickness of the insertion layer 16c. For example, the thickness of the second electron auxiliary layer 16b may be about 2-times or more greater than the thickness of the first electron auxiliary layer 16a, for example, about 2 times to about 10-times greater than the thickness of first electron auxiliary layer 16a. For example, the respective thickness of each of the first electron auxiliary layer 16a and the insertion layer 16c may be greater than or equal to about 1 nm and less than about 10 nm, whereas the second electron auxiliary layer 16b may have a thickness of about 5 nm to about 78 nm.

The aforementioned method for manufacturing the quantum dot device 10 may include forming a first electrode 11 on a substrate (not shown), forming a first hole auxiliary layer 14 and a second hole auxiliary layer 15, forming the light emitting layer 13, sequentially forming the first electron auxiliary layer 16a, the insertion layer 16c, and the second electron auxiliary layer 16b, and forming the second electrode 12.

The light emitting layer 13, the first hole auxiliary layer 14, the second hole auxiliary layer 15, the first electron auxiliary layer 16a, the insertion layer 16c, and the second electron auxiliary layer 16b may be formed by a solution process, for example, spin coating, slit coating, inkjet printing, nozzle printing, spraying, and/or doctor blade coating, but is not limited thereto. In this case, when forming adjacent layers by a solution process, the adjacent layers may be formed of solutions containing different solvents in consideration of solvent selectivity.

In one or more of the steps in the forming of the light emitting layer 13, the first hole auxiliary layer 14, the second hole auxiliary layer 15, the first electron auxiliary layer 16a, the insertion layer 16c, and the second electron auxiliary layer 16b, optionally drying and/or heat-treating after the solution process may be further performed. The heat-treating may be performed, for example, at about 50 to 300° C. for about 1 minute to 10 hours, but is not limited thereto.

The aforementioned quantum dot device 10 may be applied to various electronic devices such as, for example, a display device or a lighting device. For example, the aforementioned quantum dot device 10 may be applied to various electronic devices requiring light emission, for example, may be applied to various electronic devices such as a display device such as a TV, a monitor, a computer, a mobile, etc., or a lighting device such as a light source.

Hereinafter, the embodiments are illustrated in more detail with reference to examples. However, these examples are exemplary, and the scope of claims is not limited thereto.

### Synthesis of Quantum Dot Dispersion

### Synthesis Example 1: Synthesis of Blue Light Emitting Quantum Dots 1

### (1) Synthesis of ZnTeSe Quantum Dot Dispersion

Selenium (Se) and tellurium (Te) are respectively dispersed in trioctylphosphine (TOP) to obtain a 2 molar (M) Se/TOP stock solution and a 0.1 M Te/TOP stock solution. 0.125 mmol of zinc acetate, 0.25 mmol of oleic acid, 0.25 mmol of hexadecylamine, and 10 milliliters (mL) of trioctylamine are added to a reactor and heated under vacuum at 120° C. After 1 hour, a nitrogen gas atmosphere is added to the reactor. The reactor is heated to 240° C., the Se/TOP stock solution and the Te/TOP stock solution in a Te/Se mole ratio of 1:20 are rapidly injected into the reactor. The reactor is heated to 300° C., maintained for 30 minutes, and then, rapidly cooled to room temperature. Acetone is added to the product mixture and the resulting precipitate is separated by centrifugation. The collected precipitate is dispersed in toluene to obtain ZnTeSe quantum dot dispersion.

### (2) Synthesis of Core-Shell Quantum Dot Dispersion

To a 10 mL flask, trioctylamine, 0.6 mmol of zinc acetate, and 1.2 mmol of oleic acid are added. The flask is vacuum-treated at 120° C. for 10 minutes. Nitrogen gas is introduced into the flask and the above ZnTeSe core quantum dot dispersion is rapidly injected into the flask, followed by the rapid injection of 2 M Se/TOP solution and 1 M S/TOP solution in a Se:S mole ratio of 1.2:2.8 into the flask. The flask is heated to 340° C. and upon completion of the reaction, the reactor is cooled to room temperature and the resulting nanocrystals are separated with a centrifuge and washed with ethanol. The nanocrystals are dispersed in toluene to obtain a core-shell quantum dot dispersion.

### Synthesis Example 2: Synthesis of Blue Light Emitting Quantum Dots 2

A core-shell quantum dot dispersion is obtained by preparation in the manner as described in Synthesis Example 1 except that the Te:Se mole ratio is 1:15 in (compared to 1:20) when preparing the ZnTeSe quantum dot dispersion.

### Preparation of Dispersion for Electronic Auxiliary Layer

### Preparation Example 1

0.93 mmol of magnesium acetate tetrahydrate, 8.07 mmol of zinc acetate dihydrate, and 90 mL of dimethylsulfoxide are added a reactor and heated at 60° C. A solution including 15 mmol of tetramethylammonium hydroxide pentahydrate in 30 mL of ethanol is slowly added dropwise to the reactor over ten minutes (or about 3 mL per minute). After stirring the mixture for 1 hour, the obtained Zn_{0.85}Mg_{0.150} nanoparticles are separated from the ethyl acetate with a centrifuge and dispersed in ethanol at a concentration of 1 wt % to obtain a Zn_{0.85}Mg_{0.150} nanoparticle dispersion. The Zn_{0.85}Mg_{0.150} nanoparticles have an average particle diameter size of about 3.0 nm as measured with an UT F30 Tecnai electron microscope.

Separately, 0.06 mg of Rb₂CO₃ is added to 6 ml of ethanol and stirred overnight (6 hours or more) to prepare a Rb₂CO₃ solution (at a concentration of 0.01 mg/mL). The Zn_{0.85}Mg_{0.150} nanoparticle dispersion obtained above and the Rb₂CO₃ solution are mixed in a volume ratio of 5:1 to prepare a dispersion for an electron auxiliary layer.

### Preparation of Dispersion for Insertion Layer

### Preparation Example 2

A silica dispersion is prepared by diluting commercially available silica colloid (NexSil™ 5 Colloidal Silica) in water at 0.5 weight percent (wt %).

### Preparation of Quantum Dot Device

### Example 1

A glass substrate deposited with ITO (WF: 4.8 eV, a first electrode) is surface-treated with UV-ozone for 15 minutes, and PEDOT:PSS solution (H.C. Starks) is spin-coated on the glass substrate deposited with ITO, heat-treated under an air atmosphere at 150° C. for 10 minutes, and heat-treated again under a N2 atmosphere at 150° C. for 30 minutes to form a 30 nm-thick lower hole transport layer (HOMO: 5.3 eV, LUMO: 2.7 eV). A poly[(9,9-dioctylfluorenyl-2,7-diyl-co-(4,4′-(N-4-butylphenyl)diphenylamine] solution (TFB) (Sumitomo Corp.) is then spin-coated on the lower hole auxiliary layer and heat-treated at 150° C. for 30 minutes to form a 25 nm-thick upper hole auxiliary layer (HOMO: 5.6 eV, LUMO: 2.69 eV). The core-shell quantum dot dispersion according to Synthesis Example 1 (a peak emission wavelength: 461 nm) is spin-coated on the upper hole auxiliary layer and heat-treated at 80° C. for 30 minutes to form a 28 nm-thick light emitting layer (HOMO: 5.8 eV, LUMO: 3.1 eV, Eg: 2.7 eV). Then, the dispersion for the electron auxiliary layer according to Preparation Example 1 is spin-coated on the light emitting layer and heat-treated at 80° C. for 30 minutes to form a 5 nm-thick lower electron auxiliary layer (HOMO: 7.8 eV, LUMO: 4.3 eV, Eg: 3.5 eV). Then, the silica dispersion according to Preparation Example 2 is spin-coated on the lower electron auxiliary layer and heat-treated at 80° C. for 10 minutes to form a 5 nm-thick insertion layer (HOMO: 9.0 eV, LUMO: 3.0 eV, Eg: 6.0 eV). Then, the dispersion for the electron auxiliary layer according to Preparation Example 1 is spin-coated on the insertion layer and heat-treated at 80° C. for 30 minutes to form a 15 nm-thick upper electron auxiliary layer (HOMO: 7.8 eV, LUMO: 4.3 eV, Eg: 3.5 eV). On the upper electron auxiliary layer, aluminum (Al) is vacuum-deposited to have a thickness of 100 nm and thus form a second electrode (WF: 4.2 eV), manufacturing a quantum dot device.

### Comparative Example 1-1

A quantum dot device is manufactured in the same manner as in Example 1, except that the dispersion for the electron auxiliary layer according to Preparation Example 1 is spin-coated on the light emitting layer without an insertion layer and then heat-treated at 80° C. for 30 minutes to form a 25 nm-thick electron auxiliary layer.

### Comparative Example 1-2

A glass substrate deposited with ITO (WF: 4.8 eV, a first electrode) is surface-treated with UV-ozone for 15 minutes, and a PEDOT:PSS solution (H.C. Starks, Inc.) is spin-coated on the glass substrate deposited with ITO, heat-treated under an air atmosphere at 150° C. for 10 minutes, and then heat-treated again under a N₂ atmosphere at 150° C. for 30 minutes to form a 30 nm-thick lower hole transport layer (HOMO: 5.3 eV, LUMO: 2.7 eV). A poly[(9,9-dioctylfluorenyl-2,7-diyl-co-(4,4′-(N-4-butylphenyl)diphenylamine] solution (TFB) (Sumitomo Corp.) is spin-coated on the lower hole auxiliary layer and then heat-treated at 150° C. for 30 minutes to from a 25 nm-thick upper hole auxiliary layer (HOMO: 5.6 eV, LUMO: 2.69 eV). On the upper hole auxiliary layer, the core-shell quantum dot dispersion according to Synthesis Example 1 (a peak emission wavelength: 461 nm) is spin-coated and heat-treated at 80° C. for 30 minutes to form a 28 nm-thick light emitting layer (HOMO: 5.8 eV, LUMO: 3.1 eV, Eg: 2.7 eV). Then, the silica dispersion according to Preparation Example 2 is spin-coated on the light emitting layer and heat-treated at 80° C. for 10 minutes to form a 5 nm-thick insertion layer (HOMO: 9.0 eV, LUMO: 3.0 eV, Eg: 6.0 eV). Then, the dispersion for the electron auxiliary layer according to Preparation Example 1 is spin-coated on the insertion layer and heat-treated at 80° C. for 30 minutes to form a 20 nm-thick electron auxiliary layer (HOMO: 7.8 eV, LUMO: 4.3 eV, Eg: 3.5 eV). On the electron auxiliary layer, aluminum (Al) is vacuum-deposited to have a thickness of 100 nm and thus form a second electrode (WF: 4.2 eV), manufacturing a quantum dot device.

### Example 2

A quantum dot device is manufactured in the same manner as in Example 1, except that the core-shell quantum dot dispersion (peak emission wavelength: 476 nm) according to Synthesis Example 2 is used instead of the core-shell quantum dot dispersion (peak emission wavelength: 461 nm) according to Synthesis Example 1 to form a light emitting layer.

### Comparative Example 2-1

A quantum dot device is manufactured in the same manner as in Example 2, except that the dispersion for the electron auxiliary layer according to Preparation Example 1 is spin-coated on the light emitting layer without an insertion layer, and then heat-treated at 80° C. for 30 minutes to form a 25 nm-thick electron auxiliary layer.

### Comparative Example 2-2

A quantum dot device is manufactured in the same manner as in Example 2, except that the insertion layer (5 nm)/electron auxiliary layer (20 nm) are sequentially formed on the light emitting layer as described in Comparative Example 1-2, instead of sequentially forming the lower electron auxiliary layer (5 nm)/insertion layer (5 nm)/upper electron auxiliary layer (15 nm) on the light emitting layer.

### Evaluation

Electrical characteristics, light emitting characteristics, and life-span characteristics of quantum dot devices according to Examples and Comparative Examples are evaluated. The characteristics of the quantum dot devices are measured using a current-voltage-luminance measuring instrument (Keithley 2200, Minolta CS200).

The life-span characteristics are evaluated by measuring the degree of decreased luminance from initial luminance, while applying a current to meet a condition under which the quantum dot devices exhibit luminance of 650 nit, and T90 is evaluated by measuring time that it takes for the quantum dot devices to exhibit 90% of initial luminance.

The results are shown in Tables 1 and 2.

TABLE 1

| | | Comparative | Comparative |
|---|---|---|---|
| | Example 1 | Example 1-1 | Example 1-2 |
| EQEₘₐₓ | 7.4 | 5.4 | 7.5 |
| Lumₘₐₓ | 49931 | 46825 | 52861 |
| EQE@10000 nit | 6.2 | 4.8 | 6.4 |
| Cd/Aₘₐₓ | 7.1 | 5.4 | 7.1 |
| T90 (@650 nit) | 82 | 45 | 26 |

TABLE 2

| | | Comparative | Comparative |
|---|---|---|---|
| | Example 2 | Example 2-1 | Example 2-2 |
| EQEₘₐₓ | 5.5 | 4.9 | 5.2 |
| Lumₘₐₓ | 69079 | 56416 | 41041 |
| EQE@10000 nit | 4.9 | 3.6 | 3.3 |
| Cd/Aₘₐₓ | 7.9 | 7.3 | 7.4 |
| T90 (@650 nit) | 135 | 109 | 55 |

Referring to Tables 1 and 2, the quantum dot device according to the Examples exhibits improved electrical characteristics, light emitting characteristics, and life-span characteristics simultaneously.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A quantum dot device, comprising
a first electrode and an opposite facing second electrode,
a light emitting layer disposed between the first electrode and the second electrode, the light emitting layer comprising quantum dots,
a first electron auxiliary layer proximate to the light emitting layer and disposed between the second electrode and the light emitting layer, the first electron auxiliary layer comprising a first electron auxiliary material,
a second electron auxiliary layer proximate to the second electrode and disposed between the second electrode and the light emitting layer, the second electron auxiliary layer comprising a second electron auxiliary material, and
an insertion layer disposed between the first electron auxiliary layer and the second electron auxiliary layer, the insertion layer comprising an inorganic material,
wherein a HOMO energy level of the inorganic material of the insertion layer is deeper than a HOMO energy level of the first electron auxiliary material, and a HOMO energy level of the second electron auxiliary material, respectively.

2. The quantum dot device of claim 1, wherein
an energy bandgap of the inorganic material is greater than an energy bandgap of the first electron auxiliary material, and an energy bandgap of the second electron auxiliary material, respectively.

3. The quantum dot device of claim 1, wherein the inorganic material is inorganic nanoparticles having an energy bandgap of greater than or equal to about 4.5 eV.

4. The quantum dot device of claim 3, wherein the inorganic nanoparticles are metal oxide nanoparticles comprising Si, Al, Zr, Mg, Ca, Hf, Y, La, or a combination thereof.

5. The quantum dot device of claim 1, wherein the inorganic material is silica.

6. The quantum dot device of claim 1, wherein each of the first electron auxiliary material and the second electron auxiliary material independently comprise n-type inorganic nanoparticles.

7. The quantum dot device of claim 1, wherein each of the first electron auxiliary material and the second electron auxiliary material independently comprise n-type inorganic nanoparticles represented by Zn₁₋ₓQₓO, wherein Q is at least one metal other than Zn and 0≤x<0.5, respectively.

8. The quantum dot device of claim 1, wherein the second electron auxiliary material is the same as the first electron auxiliary material.

9. The quantum dot device of claim 1, wherein a thickness of the insertion layer is greater than or equal to about 1 nanometers and less than about 10 nanometers.

10. The quantum dot device of claim 1, wherein
a thickness of the first electron auxiliary layer is the same as or greater than a thickness of the insertion layer, and
a thickness of the second electron auxiliary layer is greater than a thickness of the first electron auxiliary layer.

11. The quantum dot device of claim 10, wherein the thickness of second electron auxiliary layer is about 2-times to about 10-times greater than the first electron auxiliary layer.

12. The quantum dot device of claim 1, wherein
the first electron auxiliary layer, and the insertion layer, have a thickness of greater than or equal to about 1 nanometer and less than about 10 nanometers, and
the second electron auxiliary layer has a thickness that is greater than the first electron auxiliary layer.

13. A quantum dot device, comprising
a first electrode and an opposite facing second electrode,
a light emitting layer disposed between the first electrode and the second electrode, the light emitting layer comprising quantum dots,
a first electron auxiliary layer proximate to the light emitting layer and disposed between the second electrode and the light emitting layer, the first electron auxiliary layer comprising first inorganic nanoparticles,
a second electron auxiliary layer proximate to the second electrode and disposed between the second electrode and the light emitting layer, the second electron auxiliary layer comprising the first inorganic nanoparticles, and optional second nanoparticles, and
an insertion layer disposed between the first electron auxiliary layer and the second electron auxiliary layer, the insertion layer comprising second inorganic nanoparticles having an energy bandgap greater than that of the first inorganic nanoparticles.

14. The quantum dot device of claim 13, wherein
an energy bandgap of the first inorganic nanoparticles is greater than or equal to about 2.0 eV and less than about 4.0 eV, and
an energy bandgap of the second inorganic nanoparticles of the insertion layer is about 4.5 eV to 10.0 eV.

15. The quantum dot device of claim 13, wherein a HOMO energy level of the second inorganic nanoparticles of the insertion layer is deeper than a HOMO energy level of the first inorganic nanoparticles.

16. The quantum dot device of claim 15, wherein a difference between the HOMO energy level of the second inorganic nanoparticles of the insertion layer and the HOMO energy level of the first inorganic nanoparticles is about 0.1 eV to about 5.0 eV.

17. The quantum dot device of claim 13, wherein
the first inorganic nanoparticles are oxide nanoparticles represented by Zn₁₋ₓQₓO, wherein Q is at least one metal other than Zn and 0≤x<0.5, and
the second inorganic nanoparticles of the insertion layer are oxide nanoparticles comprising Si, Al, Zr, Mg, Ca, Hf, Y, La, or a combination thereof.

18. The quantum dot device of claim 13, wherein
a thickness of the insertion layer is about 1 nanometer to about 8 nanometers,
a thickness of the first electron auxiliary layer is greater than or equal to about 1 nanometer and less than about 10 nanometers, and
a thickness of the second electron auxiliary layer is greater than the thickness of the insertion layer.

19. An electronic device comprising the quantum dot device of claim 1.

20. An electronic device comprising the quantum dot device of claim 13.
